(19) United States
(12) Patent Application Publication
(10) Pub. No.: US 2017/0267581 A1
(43) Pub. Date: Sep. 21, 2017

(54) BOND LAYER BETWEEN A COATING AND A SUBSTRATE

(71) Applicant: Apple Inc., Cupertino, CA (US)

(72) Inventors: Xianwei ZHAO, San Jose, CA (US); Avery P. YUEN, San Jose, CA (US); Lei YU, Shanghai (CN); Li ZHANG, Mountain View, CA (US); Wookyung BAE, Santa Clara, CA (US); Matthew S. ROGERS, San Jose, CA (US); Naoto MATSUYUKI, Kasugai (JP); Sunggu KANG, San Jose, CA (US); Enkhamgalan DORJGOTOV, Mountain View, CA (US); Cheng CHEN, San Jose, CA (US); John Z. ZHONG, Cupertino, CA (US)

(21) Appl. No.: 15/448,369

(22) Filed: Mar. 2, 2017

Related U.S. Application Data
(60) Provisional application No. 62/310,569, filed on Mar. 18, 2016.

(51) Int. Cl. C03C 17/42; B32B 9/04; C23C 14/35; C23C 14/08; C23C 14/12; B32B 17/06; C23C 14/10

(52) U.S. Cl. CPC C03C 17/42; B32B 17/06; B32B 9/04; C23C 14/10; C23C 14/083; C23C 14/12; C23C 14/35; G06F 3/041

(57) ABSTRACT

A bonding operation to increase the bond between a coating layer and substrate is described. The coating layer may be designed to resist residue on a substrate that covers a display of an electronic device. An adhesion layer including silica (SiO₂) and a catalyst or dopant, such as zirconium, may be used to bond the coating layer with the substrate. The dopant can alter the chemical nature of the adhesion layer and increase the number of chemical bonding sites at a bonding surface of the adhesion layer, thereby creating an activated bonding surface. One activated surface of the adhesion layer can be bonded with the substrate, while another activated surface of the adhesion layer can be bonded with the coating layer.

### CROSS-REFERENCE TO RELATED APPLICATION(S)

This application claims the benefit of priority to U.S. Provisional Application No. 62/310,569, filed on Mar. 18, 2016, and titled “BOND LAYER BETWEEN A COATING AND A SUBSTRATE,” the disclosure of which is incorporated herein by reference in its entirety.

### FIELD

The described embodiments relate to a coating for a substrate. The substrate may include a transparent cover layer of an electronic device, designed to cover a display of the electronic device. In particular, the described embodiments relate to an adhesion layer that provides a stronger bond between the coating and the substrate.

### BACKGROUND

An electronic device may include a touch display that allows a user to view visual information on the touch display, as well as input a command by pressing a cover glass disposed over the touch display. When a user touches the cover glass, residue on the user's finger may deposit on the cover glass. In order to resist residue buildup on the cover glass, a coating may be applied and bonded to the cover glass. However, current bonding techniques provide insufficient bonding strength between the coating and the cover glass, causing a gradual removal of the coating. While mobile devices are designed to last for several years, studies of the current bonding techniques show the coating is gradually removed from the cover glass after approximately six months. As a result, residue deposited on the cover glass becomes more difficult to remove, which may affect the user's ability to view the touch display.

### SUMMARY

In one aspect, an electronic device having an enclosure that carries internal components and a display that presents visual information is described. The electronic device may include a substrate formed of a transparent material. The substrate ca be secured with the enclosure and cover the display. The electronic device may further include an intermediate layer comprising an activated surface and a base portion. The base portion can be covalently bonded to the substrate. The electronic device may further include a coating layer. In some embodiments, the activated surface may include available covalent bonding sites that form covalent bonds with the coating layer.

In another aspect, a method for enhancing a bond between a coating and a substrate of an electronic device is described. The method may include depositing a base layer to the substrate. The method may further include applying a dopant to the base layer. The dopant may include a metal oxide that activates a bonding surface of the base layer. The method may further include depositing the coating to the bonding surface. In some embodiments, the dopant facilitates chemical bonding of the base layer with the coating.

In another aspect, a method for bonding a coating with a substrate of an electronic device, the coating configured to resist residue is described. The method may include depositing an adhesion layer on the substrate. The method may further include doping the adhesion layer with an activator. In some embodiments, the activator activates a bonding surface of the adhesion layer. The method may further include depositing the coating on the bonding surface to chemically bond the coating with the bonding surface.

Other systems, methods, features and advantages of the embodiments will be, or will become, apparent to one of ordinary skill in the art upon examination of the following figures and detailed description. It is intended that all such additional systems, methods, features and advantages be included within this description and this summary, be within the scope of the embodiments, and be protected by the following claims.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates an isometric view of an embodiment of an electronic device, in accordance with some embodiments;

FIG. 2 illustrates a plan view of an embodiment of a protective layer, in accordance with some embodiments;

FIG. 3 illustrates a cross sectional view of the protective layer shown in FIG. 2 taken along line A-A, showing various layers disposed over the protective layer, in accordance with some embodiments;

FIG. 4 illustrates a plan view of a deposition apparatus designed to sputter multiple layers onto a substrate, in accordance with some embodiments;

FIG. 5 illustrates a partial view of a deposition apparatus, further showing molecules from a target depositing on a substrate, in accordance with some embodiments;

FIG. 6 illustrates an embodiment of a molecular network of an intermediate layer, in accordance with some embodiments;

FIG. 7 illustrates the intermediate layer shown in FIG. 6 subsequent to a hydrolysis operation to produce hydroxyl (OH) bonding sites;

FIG. 8 illustrates a series of chemical reactions that forms covalent bonds between an intermediate layer and a substrate, in accordance with some embodiments;

FIG. 9 illustrates a flowchart showing a method for bonding a coating with a substrate of an electronic device, the coating configured to resist residue, in accordance with some described embodiments; and

FIG. 10 illustrates a flowchart showing a method for bonding a coating with a substrate of an electronic device, in accordance with some described embodiments.

Those skilled in the art will appreciate and understand that, according to common practice, various features of the drawings discussed below are not necessarily drawn to scale, and that dimensions of various features and elements of the drawings may be expanded or reduced to more clearly illustrate the embodiments of the present invention described herein.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

In the following detailed description, references are made to the accompanying drawings, which form a part of the description and in which are shown, by way of illustration, specific embodiments in accordance with some described embodiments. Although these embodiments are described in sufficient detail to enable one skilled in the art to practice the described embodiments, it is understood that these examples are not limiting such that other embodiments may be used, and changes may be made without departing from the spirit and scope of the described embodiments.

The described embodiments relate to a coating applied to a protective layer of an electronic device, with the protective layer covering, or overlaying, a touch display of the electronic device. The protective layer may include a cover glass that provides a transparent layer over the touch display. The coating is designed to resist residue buildup on the protective layer. For example, the user may leave residue when touching the protective layer. By resisting residue and other deposits, the protective layer can maintain a touch display that is easier to view.

The coating, or coating layer, may include a fluorocarbon polymer or fluorine-based polymer. This may include a perfluorinated polymer (PFP). The protective layer may include glass (including silica, SiO₂), sapphire, or onyx, as non-limiting examples. In order to bond the coating with the protective layer, an intermediate layer may be used. The intermediate layer may interact with the coating and/or the protective layer to chemically bond with the coating and/or protective layer. The intermediate layer may increase number of chemical bonds by increasing the number of available bonding locations between the coating and the intermediate layer, and/or between the protective layer and the intermediate layer. The intermediate layer may include silica (SiO₂) doped with a catalyst, such as zirconium.

A deposition operation, such as a sputtering operation, may be used to combine and deposit silica (SiO₂) and zirconia (ZrO₂) on the protective layer. The sputtering operation may include a sputtering apparatus having a chamber designed to provide a low-pressure (near vacuum) environment in the chamber. In some embodiments, the chamber includes one or more silicon (Si) sputter targets and one or more zirconium (Zr) sputter targets. Both the silicon and zirconium may react with the limited air in the low-pressure chamber to form silica and zirconia, respectively. In some embodiments, the protective layer is placed in the chamber and rotated relative to the sputter target(s) in order to deposit silica and zirconia molecules onto the protective layer. The intermediate layer, formed by the combination of silica and zirconia, may primarily include silica, with the percent composition of the zirconia ranging approximately from 1 to 10 percent.

Zirconium may include one or more desirable properties, such as an ability to break a bond between silicon and oxygen atoms within the silicon dioxide network of silica, as a zirconium atom is relatively large compared to a silicon atom. This, along with a hydrolysis operation, may modify the silicon dioxide network of silica, causing a formation of hydroxyl (OH) bonding sites at surfaces of the intermediate layer, which can be used to bond with a subsequently deposited fluorocarbon-based coating. Also, zirconium may include a relatively low electronegativity (relative to silicon) such that the zirconium atoms can more readily lose an electron and bond with oxygen (O). Accordingly, the doped intermediate layer provides more reactive OH bonding sites for bonding with both the coating and the protective layer. As a result of the increased bonding sites, the coating can remain bonded with the intermediate layer for a relatively longer period of time, and accordingly, can remain on the protective layer for a relatively longer period of time.

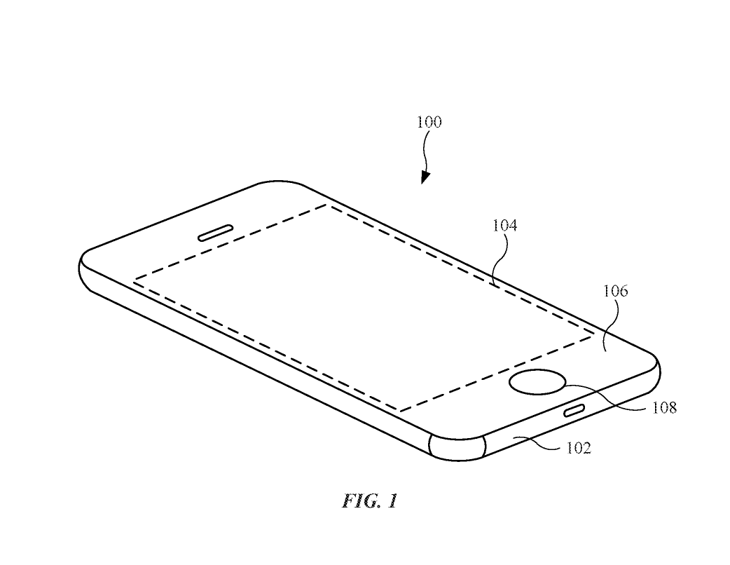

These and other embodiments are discussed below with reference to FIGS. 1-10. However, those skilled in the art will readily appreciate that the detailed description given herein with respect to these Figures is for explanatory purposes only and should not be construed as limiting.

FIG. 1 illustrates an isometric view of an embodiment of an electronic device 100, in accordance with some described embodiments. In some embodiments, the electronic device 100 is a tablet computer device. In other embodiments, the electronic device 100 is a wearable electronic device, including an electronic watch having multiple bands (not shown) designed to secure to the electronic watch to an appendage (such as a wrist) of a user. In the embodiment shown in FIG. 1, the electronic device 100 is a mobile wireless communication device, such as a smartphone. As shown, the electronic device 100 may include an enclosure 102. The enclosure 102 may be formed from a rigid material, such as a metal (including aluminum or aluminum alloy) or a durable plastic. The electronic device 100 may also include a display assembly 104 designed to provide visual information in the form of textual information, video images, and other forms of media images. The display assembly 104 may include a touch sensitive capacitive layer designed to allow the electronic device 100 receive a gesture or command by a capacitive coupling between an appendage (such as a finger) of a user and the touch sensitive capacitive layer. In other words, the display assembly 104 may receive a touch input from the user.

The electronic device 100 may further include a protective layer 106, sometimes referred to as a cover glass, covering the display assembly 104. The protective layer 106 may include a transparent material extending to an outer perimeter defined by the enclosure 102. As non-limiting examples, the protective layer 106 may include glass, sapphire, or onyx. Further, the protective layer 106 may include a coating designed to resist residue or other materials that may deposit on the protective layer 106, by for example, the user contacting the protective layer 106. This will be discussed and shown below. The electronic device 100 may further include a button 108 designed to generate an input or command in response to a touch and/or force applied to the button 108.

FIG. 2 illustrates a plan view of an embodiment of a protective layer 206, in accordance with some described embodiments. The protective layer 206 is sometimes referred to as a cover glass. However, the protective layer 206 may include other forms of transparent materials. The protective layer 206 may include may include any material (or materials) and any feature (or features) previously described for a protective layer. As shown, the protective layer 206 may include openings, such as a first opening 202 and a second opening 204, designed to facilitate interaction with an electronic device (not shown) that includes the protective layer 206. However, in some embodiments (not shown), the protective layer 206 is free of any openings.

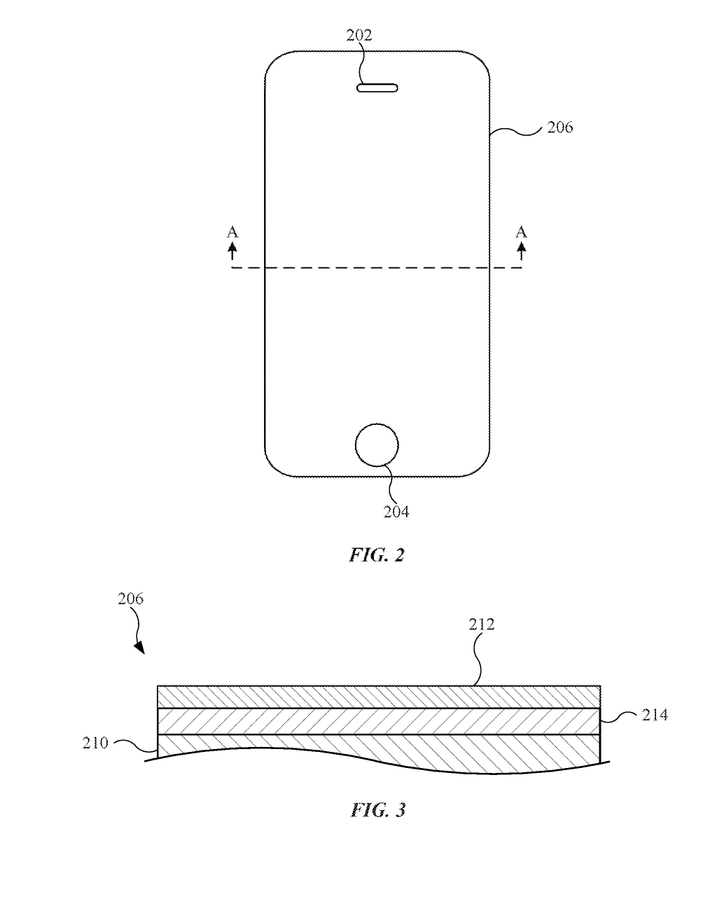

The protective layer 206 may be designed to resist residue or other materials that deposit on the protective layer 206. In this regard, the protective layer 206 may include one or more layers disposed over the protective layer 206. For example, FIG. 3 illustrates a cross sectional view of the protective layer 206 shown in FIG. 2 taken along line A-A, in accordance with some described embodiments. The protective layer 206 may include a substrate 210, which may include a material (or materials) including glass, sapphire, or onyx, as non-limiting examples. Accordingly, the substrate 210 may provide a transparency such that a display assembly (not shown) may be viewed through the substrate 210. Further, the protective layer 206 may include a coating layer 212, or coating, disposed over the substrate 210. The coating layer 212 may include various types of compositions. Also, the coating layer 212 may be located over any suitable location of the substrate 210. Alternatively, the coating layer 212 may be positioned at selected, or predetermined, locations. In some embodiments, the coating layer 212 is designed to provide resistance to residue, smears, smudge, blemishes, or the like. In this regard, the coating layer 212 may provide a non-stick surface that enhances the appearance of the protective layer 206 by limiting or preventing residue from remaining over the substrate 210. Thus, the material of coating layer 212 can be chosen to provide aesthetic qualities to the protective layer 206. In some embodiments, the coating layer 212 includes a fluorine-based polymer, such as a fluoropolymer. In other embodiments, the coating layer 212 includes polytetrafluoroethylene (PTFE). Similar to the substrate 210, the coating layer 212 may be generally transparent or translucent to visible light.

In order to limit or prevent the coating layer 212 from wearing off from the substrate 210, the protective layer 206 may further include an intermediate layer 214 designed to bond with the substrate 210 and the coating layer 212. In this regard, the intermediate layer 214 may be referred to as an adhesion layer. Like the substrate 210 and the coating layer 212, the intermediate layer 214 can be generally transparent or translucent to visible light such that an underlying display assembly (not shown) can be visible therethrough. The intermediate layer 214 may include multiple compounds designed to chemically bond with the substrate 210 and/or the coating layer 212, and enhance the likelihood of the coating layer 212 remaining disposed over the substrate 210 during normal use. In some embodiments, the intermediate layer 214 includes silicon dioxide (SiO₂) in the form of a network of silicon and oxygen atoms. Further, during the deposition of the intermediate layer 214, the silicon dioxide of the intermediate layer 214 may be doped with, or exposed to, zirconium atoms that deposit within and modify the network of silicon and oxygen atoms of the intermediate layer 214. In particular, the zirconium can create more non-bridging oxygen moieties, i.e., “free” oxygen (O), which can culminate in altering the surface of the intermediate layer 214, which may enhances bonding, including chemical bonding, with the substrate 210. Further, these changes to the intermediate layer 214 may also enhance bonding, including chemical bonding, with the coating layer 212. In this regard, zirconium (or zirconia) may also be referred to as an activator or an activating agent. It should be noted that in some embodiments, doping agents other than zirconium could be used. For example, in some embodiments, the dopant includes aluminum and/or titanium.

FIG. 4 illustrates a plan view of a deposition apparatus 300 designed to sputter multiple layers onto a substrate 310, in accordance with some embodiments. The deposition apparatus 300 may include an evaporation chamber, such as a physical vapor deposition (PVD) chamber. However, in the embodiment shown in FIG. 4, the deposition apparatus 300 includes a sputtering apparatus designed to deposit a material (or materials) by a sputtering operation. As shown, the deposition apparatus 300 may include a chamber 302 that is sealed such that air may be pumped out of the chamber 302 to create a low-pressure (near vacuum) environment. Also, the substrate 310 may be disposed in the chamber 302. It should be noted that the substrate 310 may be substantially similar to the substrate 210 (shown in FIG. 3), and accordingly, the substrate 310 may be part of a protective layer (e.g., cover glass) previously described.

The substrate 310 may be secured with a rotary table 320 designed to rotate the substrate 310 and expose the substrate 310 to multiple targets in the deposition apparatus 300, with each target emitting materials, while under the low-pressure environment, that deposit onto the substrate 310 during the sputtering operation. For example, the deposition apparatus 300 may include a first target 322. The first target 322 may include a first pair of targets, each of which may include silicon, and in some cases, may include pure silicon (or approximately 100% silicon). The deposition apparatus 300 may include a second target 324 that includes a second pair of targets, each of which having a material substantially similar to that of the first target 322, e.g., silicon. The deposition apparatus 300 may further include a third target 326 that includes a pair of targets, each of which including a doping material such that material emitted from the first target 322 and the second target 324 are doped with the material emitted from the third target 326. In this regard, the third target 326 may include targets having a doping material, such as zirconium. Further, in some embodiments, the third target 326 may include targets having zirconium compositions in the range of about 5% to about 20%, by atomic weight, while the remainder may include another compound, such as silica. Also, the deposition apparatus 300 may include a power source 328 that supplies power by electromagnetic induction. The power source 328 may also include an inductively coupled plasma (ICP) device.

During operation of the deposition apparatus 300, the rotary table 320 may rotate the substrate 310 while silicon and zirconium particles are emitted from their respective targets. The deposition apparatus 300 may be designed to form ionized gas molecules that strike the aforementioned targets, causing molecules of the target to release from the targets, some of which may deposit on a surface of the substrate 310. Also, the silicon and zirconium may react with air in the chamber 302 to form silica and zirconia, respectively, on the substrate 310. The silica and zirconia may combine to define an intermediate layer (similar to the intermediate layer 214, shown in FIG. 3). The operation may continue until a desired amount of a deposition (that defines the intermediate layer) is reached. For example, once deposited on the substrate 310, an intermediate layer (not shown) formed by the deposition apparatus 300 may include a thickness approximately in the range of 5 nanometers (nm) to 15 nm. Also, by percent composition, the zirconia (ZrO₂) may be approximately in the range of 1% to 10%, while the silica (SiO₂) may be approximately in the range of 99% to 90% silica. For example, when the zirconia composition is 5%, the silica composition is 95%. Also, in one particular embodiment, the percent composition of zirconia is about 3% to 6%, and the percent composition of silica (SiO₂) is about 94% to 97%. These percentages and thicknesses may vary according to other desired parameters. Also, in some cases, zirconium may be substituted aluminum or titanium, as non-limiting examples.

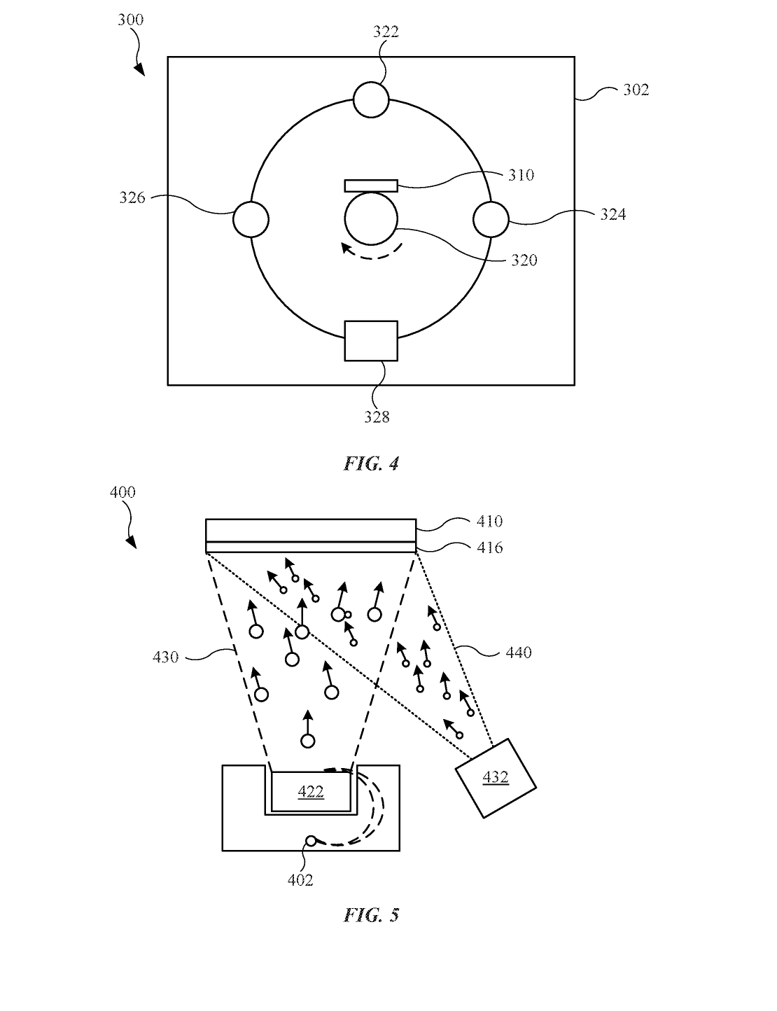

FIG. 5 illustrates a partial view of a deposition apparatus 400, further showing molecules 430 from a target 422 depositing on a substrate 410, in accordance with some described embodiments. The deposition apparatus 400 may include one or more features used in the deposition apparatus 300 (shown in FIG. 4). The molecules 430 from the target 422 may be formed from silica, as an example. The molecules 430 may be ionized due in part to an electron beam gun 402 to that directs electrons in a direction toward the target 422. A magnetic field (not shown) may also direct the electrons. Also, during deposition of materials from the target 422, an emitter 432 may direct molecules 440 (also ionized) that combine with the molecules 430 from the target 422 to form a film 416 that may be a combination of a coating layer bonded with an intermediate layer, with the intermediate layer also bonded with the substrate 410. The coating layer may be designed to resist residue.

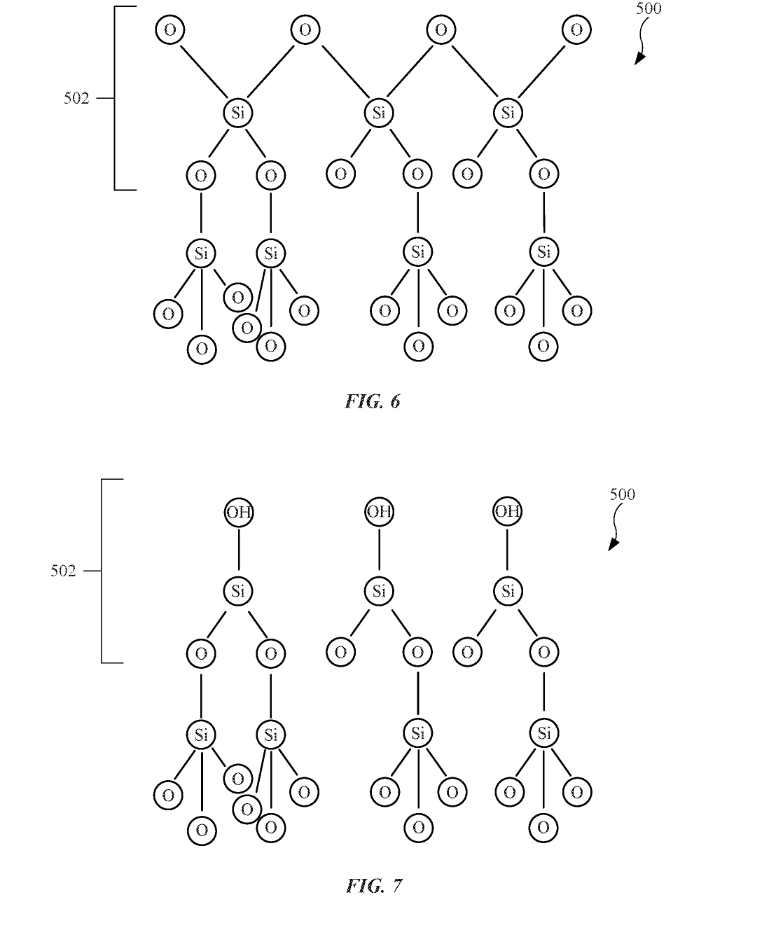

FIGS. 6 and 7 illustrate an exemplary relationship between molecules within an intermediate layer 500 before and after a hydrolysis operation. As shown, the intermediate layer 500 includes a network of covalently bonded silicon (Si) and oxygen (O) atoms. The region 502 may represent a surface region of the intermediate layer 500.

FIG. 6 illustrates the intermediate layer 500 prior to hydrolysis where the region 502 is not activated, while FIG. 7 illustrates the intermediate layer 500 subsequent to undergoing one or more operations to produce hydroxyl (OH) bonding sites at the region 502. The operations may include hydrolysis activated with heating, plasma exposure, and/or silica sol gel such that oxygen and water can combine to form OH bonding sites at the region 502. The OH bonding sites can covalently bond with atoms within a subsequently deposited coating layer. In this manner, the region 502, created by hydrolysis, includes an activated surface region for bonding the intermediate layer 500 with a substrate and/or a coating layer.

According to some embodiments described herein, methods include doping the intermediate layer 500 with a dopant (not shown) so as to increase the number of OH bonding sites at the region 502. In some embodiments, the dopant includes zirconium. The relatively large size and relatively low electronegativity of zirconium, as compared to silicon, may cause breakage of the Si—O bonds when inserted within the SiO₂ network, which in turn changes the surface composition at the region 502. In particular, the surface composition includes more OH bonding sites for bonding with a substrate or a subsequently deposited cover layer (e.g., fluoropolymer layer). In this manner, the region 502 can become an activated bonding surface. Once incorporated within the SiO₂ network, the zirconium can bond with oxygen to form zirconium oxide or zirconium dioxide (zirconia). Thus, incorporating zirconium within the intermediate layer 500 can also increase the hardness of the intermediate layer 500. Note that the dopant is not limited to zirconium and may alternatively or additionally include a different dopant such as aluminum or titanium. In some embodiments, the dopant includes two or more of zirconium, aluminum or titanium. As with zirconium, the aluminum can bond with oxygen within the silica network to form aluminum oxide or aluminum dioxide (alumina), and the titanium can bond with oxygen to form titanium oxide or titanium dioxide (titania).

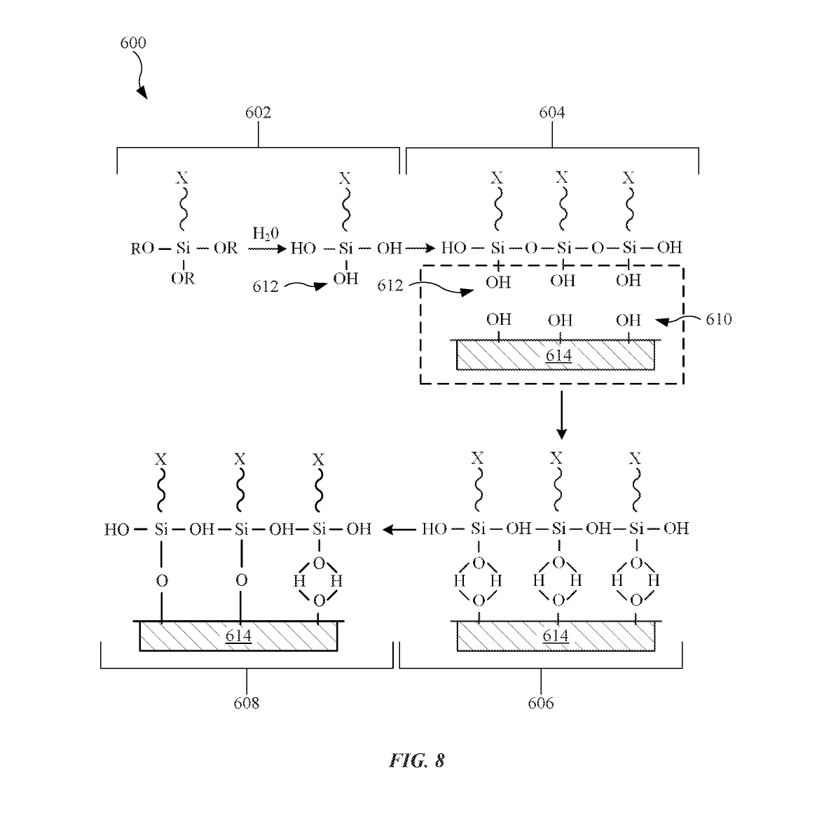

FIG. 8 illustrates a series 600 of chemical reactions for chemically bonding an intermediate layer with a protective layer, in accordance with some embodiments. At a first step 602, the intermediate layer is hydrolyzed to form OH bonding sites 612 at a surface of the intermediate layer, such as described above with reference to FIGS. 6 and 7. “R” can refer to any suitable species such as an organic species, and “X” can represent long polymer chains within a coating layer. As described above, doping the intermediate layer with zirconium (and/or aluminum and/or titanium) can modify the molecular network of silica within the intermediate layer so as to increase the density of OH bonding sites at a bonding surface of the intermediate layer.

In a second step 604, the substrate 614, which also includes OH bonding sites 610, is introduced. As described above, the substrate 614 may include an inorganic material such as a glass, sapphire, or onyx. Further, FIG. 8 shows a third step 606 showing hydrogen bonding between OH bonding sites 612 of the intermediate layer and OH bonding sites of the substrate 614. FIG. 8 further illustrates a fourth step 608 that shows covalent bonding of O atoms with Si atoms of the intermediate layer and Si atoms of the substrate 614 after a dehydration operation. Dehydration and condensation can be accomplished by heating the intermediate layer and the substrate 614. Since the intermediate layer is doped, it includes a higher density of OH bonding sites compared to an undoped intermediate layer. Thus, there will be more covalent bonds formed between the intermediate layer and the substrate 614.

The increased number of OH bonding sites can also cause the intermediate layer to form a stronger bond with bonding sites of the coating layer (represented by “X”) as compared to an undoped intermediate layer. In some embodiments, the increased number of OH bonding sites also forms covalent bonds with bonding sites of the coating layer. For example, the coating layer can also have OH bonding sites that bond with corresponding OH bonding sites of the intermediate layer. After dehydration, covalent bonds between the coating layer and intermediate layer can be formed. This results in a coating layer that is more firmly bonded with the substrate. In some embodiments, the doped intermediate layer causes the coating layer to remain adhered with the substrate twice as long as an undoped intermediate layer, as measured using abrasion wear tests. Note that in some embodiments the intermediate layer is deposited onto the substrate 614, followed by depositing of the coating layer on the intermediate layer.

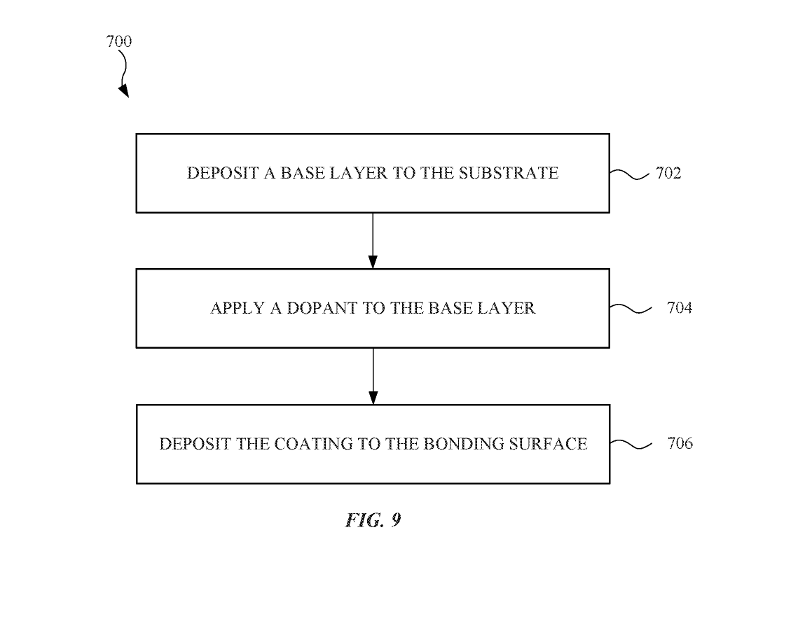

FIG. 9 illustrates a flowchart 700 showing a method for enhancing a bond between a coating and a substrate of an electronic device, in accordance with some described embodiments. The coating may include a residue-resistant coating configured to oppose residue buildup on the substrate. In step 702, a base layer is applied to the substrate. The base layer may include silicon dioxide, or silica.

In step 704, a dopant to the base layer. The dopant may a metal oxide that activates a bonding surface of the base layer. The metal oxide may include metal oxide network that includes zirconium oxide, titanium oxide, and/or aluminum oxide. In some embodiments, the metal oxide network includes. In some embodiments, a sputter deposition apparatus is used. The dopant can increase the number of OH bonding sites at surfaces of the base layer (as compared to the base layer without the dopant). In some cases, increasing the OH bonding sites of the base layer increases the bond strength between the substrate and the base layer by creating more covalent bonds between the two. Alternatively, in some embodiments, the base layer can be applied with the dopant by a co-sputtering operation, and accordingly, the base layer can include with a base material (e.g., silicon oxide) along with the metal oxide network (e.g., silicon dioxide).

In step 706, the coating is deposited on a surface of the bonding surface. The coating may include a polymer material, such as a fluorocarbon polymer molecule (or molecules). The increased number of OH bonding sites at the surface of the first layer can increase the bond strength between the first layer and the second layer. In some embodiments, the increased number of OH bonding sites creates more covalent bonds between the first layer and the second layer.

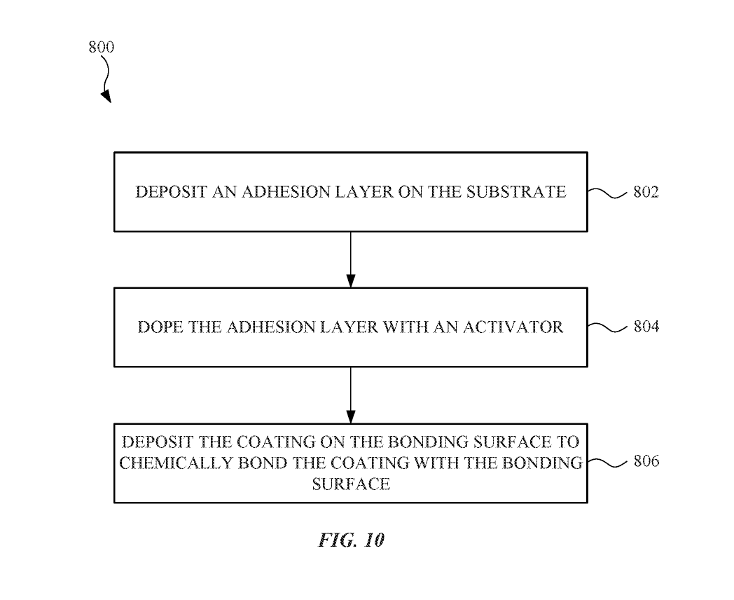

FIG. 10 illustrates a flowchart 800 showing a method for enhancing a bond between a coating and a substrate of an electronic device, in accordance with some described embodiments. The coating may include a smudge-resistant, or residue-resistant, coating designed to resist material buildup on the substrate. In step 802, an adhesion layer is deposited on the substrate. The adhesion layer may include silicon dioxide. Also, the adhesion layer is designed to adhere the coating with the substrate.

In step 804, the adhesion layer is doped with an activator. The activator is designed to form a bonding surface at the adhesion layer. The activator may include a dopant, such as a metal oxide. In this regard, the activator modifies a molecular network of the adhesion layer to form bonding sites at the bonding surface of the adhesion layer.

In step 806, the coating is deposited on the bonding surface to chemically bond the coating with the bonding surface. The bonding sites may include hydroxyl bonding sites used by the metal oxide to chemically bond with the coating and the substrate.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device having an enclosure that carries internal components and a display that presents visual information, the electronic device comprising:
a substrate formed of a transparent material, the substrate secured with the enclosure and covering the display;
an intermediate layer comprising an activated surface and a base portion, the base portion covalently bonded to the substrate; and
a coating layer, wherein the activated surface comprises available covalent bonding sites that form covalent bonds with the coating layer.

2. The electronic device of claim 1, wherein the base portion comprises silicon dioxide and the activated surface comprises zirconium dioxide.

3. The electronic device of claim 1, wherein the coating layer include silicone dioxide with silicon dioxide.

4. The electronic device of claim 1, wherein the activated surface causes the intermediate layer to form multiple hydroxyl bonding sites.

5. The electronic device of claim 4, wherein the multiple hydroxyl bonding sites are used by the intermediate layer to chemically bond with the base portion and the substrate.

6. The electronic device of claim 1, wherein the substrate comprises silicon dioxide.

7. The electronic device of claim 1, wherein the coating layer comprises a fluorocarbon polymer.

8. A method for enhancing a bond between a coating and a substrate of an electronic device, the method comprising:
depositing a base layer to the substrate;
applying a dopant to the base layer, the dopant comprising a metal oxide that activates a bonding surface of the base layer; and
depositing the coating to the bonding surface, wherein the dopant facilitates chemical bonding of the base layer with the coating.

9. The method of claim 8, wherein the base layer comprises silicon dioxide and the dopant comprises zirconium.

10. The method of claim 8, wherein the dopant causes the metal oxide to chemically bond with the substrate.

11. The method of claim 10, wherein the dopant causes the base layer to form multiple hydroxyl bonding sites.

12. The method of claim 11, wherein the multiple hydroxyl bonding sites are used by the metal oxide to chemically bond with the coating and the substrate.

13. The method of claim 8, wherein the substrate comprises silicon dioxide.

14. The method of claim 8, wherein depositing the coating comprises forming a fluorocarbon polymer.

15. The method of claim 8, wherein depositing the coating to the bonding surface comprises applying a residue-resistant coating to the bonding surface.

16. A method for bonding a coating with a substrate of an electronic device, the coating configured to resist residue, the method comprising:
depositing an adhesion layer on the substrate;
doping the adhesion layer with an activator, wherein the activator activates a bonding surface of the adhesion layer; and
depositing the coating on the bonding surface to chemically bond the coating with the bonding surface.

17. The method of claim 16, wherein the activator modifies a molecular network of the adhesion layer so as to form bonding sites at the bonding surface of the adhesion layer.

18. The method of claim 17, wherein the bonding sites bond with corresponding bonding sites on the coating to form covalent bonds between the adhesion layer and the coating.

19. The method of claim 16, wherein the coating comprising a fluoropolymer.

20. The method of claim 16, wherein the substrate comprises a transparent material that overlays a display assembly of the electronic device.
